(19) United States
(12) Patent Application Publication
(10) Pub. No.: US 2026/0118290 A1
(43) Pub. Date: Apr. 30, 2026

(54) DETERMINATION OF PHYSICAL PROPERTIES OF CRYSTALS BY FOCUSED SCANNING ELECRON MICROSCOPE

(71) Applicant: Applied Materials Israel Ltd., Rehovot (IL)

(72) Inventor: Konstantin CHIRKO, Rehovot (IL)

(21) Appl. No.: 19/362,269

(22) Filed: Oct. 17, 2025

(30) Foreign Application Priority Data
Oct. 28, 2024 (IL) 316620

(51) Int. Cl. G01N 23/201

(52) U.S. Cl. CPC G01N 23/201; G01N 2223/6116

(57) ABSTRACT

A method of using a scanning electron microscope (SEM) to determine crystalline features of a crystalline sample, the method including: (a) imaging an area on the crystalline sample using a focused SEM electron beam, (b) recording intensity of reflection of the focused SEM electron beam from a location within the imaged area, (c) recording a tilt angle of the crystalline sample, (d) changing the tilt angle of the crystalline sample and repeating steps (a)-(c) a plurality of times for the imaged area, (e) analyzing the recorded tilt angles and intensities of reflection, (f) using the analysis to determine at least one crystalline feature of the crystalline sample. Related apparatus and methods are also described.

This application claims the benefit of priority from Israeli Patent Application No. 316620, filed Oct. 28, 2024, which is incorporated herein by reference.

### TECHNOLOGICAL FIELD

The present disclosure, in some embodiments thereof, relates to a method for determining physical features of crystals, such as, by way of some non-limiting examples semiconducting crystals and wafers, using a focused beam scanning electron microscope (SEM) and, more particularly, but not exclusively, to a method for determining crystal lattice spacing using a focused beam SEM, and even more particularly, but not exclusively, to a method for determining physical features of crystals in an area sized similarly to a single integrated circuit device using a focused beam SEM.

### BRIEF DESCRIPTION OF THE DRAWING(S)

Some embodiments of the disclosure are herein described, by way of example only, with reference to the accompanying drawings and images. With specific reference now to the drawings and images in detail, it is stressed that the particulars shown are by way of example and for purposes of illustrative discussion of embodiments of the disclosure. In this regard, the description taken with the drawings makes apparent to those skilled in the art how embodiments of the disclosure may be practiced.

In the drawings:

FIGS. 1A and 1B are simplified illustrations of an example three-lens scanning electron microscope (SEM) according to prior art;

FIG. 2A is a SEM image of Kikuchi lines produced using a parallel, unfocused electron beam at a tilt angle of 34 degrees to a lattice plane of a silicon wafer;

FIG. 2B is a SEM image produced using a focused electron beam with a central optical axis at a tilt angle of 34 degrees to a lattice plane of a of a silicon wafer according to an example;

FIGS. 2C and 2D are simplified illustrations of measuring crystal orientation according to an example;

FIGS. 3A, 3B and 3C are simplified illustrations of various crystalline and amorphous or non-crystalline samples imaged by a focused SEM beam at various tilt angles, according to some examples;

FIG. 4 is a graph of qualitative values of reflected radiation amplitude of the various crystalline and amorphous or non-crystalline samples of FIGS. 3A, 3B and 3C, according to some examples;

FIG. 5 shows a simplified cross-sectional drawing of a strained epitaxial layer on a substrate layer according to an example;

FIG. 6 shows a simplified cross-sectional drawing of a relaxed epitaxial layer on a substrate layer according to an example; and

FIG. 7 is a simplified flow chart illustration of a method of using a scanning electron microscope (SEM) to determine crystalline features of a crystalline sample, according to an example.

### DETAILED DESCRIPTION OF EXAMPLES

The present disclosure, in some embodiments thereof, relates to a method for determining physical features of crystals, such as, by way of some non-limiting examples semiconducting crystals and wafers, using a focused beam scanning electron microscope (SEM) and, more particularly, but not exclusively, to a method for determining crystal lattice spacing using a focused beam SEM, and even more particularly, but not exclusively, to a method for determining physical features of crystals in an area sized similarly to a single integrated circuit device using a focused beam SEM.

It is noted that using a focused beam SEM to determine physical features of crystals produces a synergistic combination of imaging and determination of crystal properties.

### Overview

Some example SEM-based methods for analyzing crystal properties are described below.

Crystal property analysis may be used to determine lattice structure and lattice orientation as well as measuring lattice parameters such as lattice constant and angle between lattice planes. In semiconductor manufacturing, these parameters may be important for measuring properties such as lattice strain and rotation, influencing device performance and process quality.

### Bragg's Law

Bragg's Law states that when plane wave radiation, such as, by way of a non-limiting example, a plane SEM electron beam having a specific energy and wavelength, is incident onto a crystal surface, its angle of incidence, θ, will reflect back with a same angle of scattering, θ, and, when the path difference, d is equal to a whole number, n, of wavelength, a constructive interference will occur.

Electron beam wavelength is inversely proportional to electron velocity.

Taking for example a crystal with aligned planes of lattice points separated by a lattice spacing d₁ and monochromatic plane radiation incident upon the crystal at an angle θ, the rays reflect off atoms of the crystal lattice as radiation. A path difference between a ray reflected at one atom and a ray reflected at another atom can be expressed in terms of the lattice spacing d₁ and the incident angle θ:

If the path difference is equal to an integer multiple of the wavelength, then scattered radiation rays will arrive at a topmost crystal plane in the same phase. In other words, the scattered radiation will undergo constructive interference, and the crystal will appear to have reflected the X-radiation. If, however, this path difference condition is not satisfied, then destructive interference will occur.

### Bragg's Law:

$$n λ = 2 d s in θ \qquad Equation 1$$

where:
λ is the wavelength of the radiation,
d is the spacing of the crystal layers,
θ is the incident angle (the angle between incident ray and the scattering plane), and
n is an integer.

The formula provided by Bragg's Law can be applied to determine crystal lattice spacing by determining at which incident angle θ constructive interference occurs.

An electron beam in a SEM can be viewed as a form of radiation.

When using a SEM, the wavelength of the radiation λ is determined by the beam energy of the electrons.

The angle of incidence of the electron beam optic axis is determined by a tilt angle of the SEM specimen stage to the electron beam optic axis.

A method named electron channeling pattern (ECP) is used for characterization of bulk uniform crystal samples, including determining of Bragg angles for different crystal planes. This method is based on a physical phenomenon called channeling. This phenomenon is produced by the behavior of reflection of electrons from a sample depending non-monotonically on an angle between an incident electron beam and lattice planes. This phenomenon is described in more detail, for example, in an article by David C. Joy, titled “Electron Channeling patterns in the scanning electron microscope”, published in Journal of Applied Physics 53 (1982).

For manifestation of the channeling to be significant, the angle of incidence of all electrons in the beam should be equal, which implies that the electron beam is parallel and not focused. The diameter of the parallel beam limits spatial resolution of this method, which typically is of order of 1 μm.

In practice, to acquire an ECP image, a parallel electron beam scans across a sample of interest in a low-magnification SEM mode. The incidence angle of the beam to the crystal lattice plane varies over a range of several degrees. In other words, the lattice plane receives radiation from a beam that is on the order of 1 μm wide, so receives radiation waves at different angles.

It is noted that because of optical properties of a SEM microscope, the electron beam intended to be parallel may not be ideally parallel, but its angle of convergence is usually less than 1 milliradian (mrad), which is significantly smaller than a typical angle of convergence of a focused beam in SEM high resolution mode, which may be 5-15 mrad.

An image is recorded with a detector which integrates electrons leaving the sample in many exit directions during a certain time interval (exposure time). In such an image, each pixel represents a certain angle between incident electrons and the crystal lattice. The image represents a channeling pattern consisting of sharp dark and bright lines and bands, called Kikuchi lines and bands. Variations in brightness of pixels are dictated by angle-dependent reflectance of lattice planes. Distance between lines contains information on crystalline structure, which information may be extracted and analyzed by known methods, such as described in an article by Wilkinson, A. J. titled “Methods for determining elastic strains from electron backscatter diffraction and electron channeling patterns”, published in Materials Science and technology, pp. 79-84, 1997.

One notes that an ECP image is produced using a parallel beam, at some possible fixed tilt angle to a normal to the crystal surface, optionally at a zero-tilt angle, while scanning a surface of a crystal sample.

A method named Electron Back Scattered Diffraction (EBSD) is another SEM-based method of crystal characterization. EBSD also provides an image of Kikuchi lines and bands of a sample of interest. In EBSD local image intensity changes based on the angle at which electrons leave the sample. A location on a crystal sample is illuminated with a focused electron beam at a large angle of incidence to the surface, (typically, 60 degrees or more), which angle is constant during the imaging procedure. A high-energy electron beam (typically 20 kV) is focused on a small volume and scatters with a spatial resolution of ˜20 nm at the specimen surface. An image is recorded with a dedicated EBSD detector, where different pixels represent different exit angles of electrons relative to the crystal lattice. The electron beam illuminates the same location and does not move until all pixels in the image are filled with a required number of electrons; then the electron beam may be moved to a next location. This method is described in detail in an article by Wilkinson, A. J., titled “Measurement of elastic strains and small lattice rotations using electron back scatter diffraction”, published in Ultramicroscopy 62, pp. 237-247, 1996.

One notes that EBSD works at large tilt angles, which are not typically possible for large flat samples such as a silicon wafer. One potential problem with tilting a sample crystal inside an electron microscope may be the size of the sample crystal. In the semiconductor industry, the sample crystal may be a silicon wafer having a large diameter, for example a diameter up to 300 millimeters, and tilting the wafer may be limited within the confines of a standard electron microscope. Tilting an entire wafer may be limited in the range of possible angles.

A problem of EBSD utilization in semiconductor industry is that its use in advanced 3D modes of manufacturing (e.g. gate-all-around or C-FET) may be limited. 3D features may either obstruct crystalline elements of interest from a line of sight of an illuminating electron beam or may perturb spatial distribution of electrons leaving the sample. Both phenomena are obstacles to obtaining an adequate Kikuchi pattern, especially in cases where relatively tall 3D structures obstruct crystal areas which are in shadow from the electron beam due to the large tilt angle.

It is noted that examples of the new methods presented herein are suitable for cases where relatively tall 3D structures might obstruct crystal areas which may be in shadow from the electron beam with a large tilt angle, since small tilt angles may be used, that is, small angles from a normal to a semiconductor wafer, or a crystal sample surface.

A problem with using EBSD in the semiconductor industry is that the electron beam illuminates the same location and does not move until all pixels in the image are filled with a required number of electrons; then the electron beam may be moved to a next location. This leads to a limitation of throughput in inspecting semiconductor wafers.

To summarize features associated with the methods described above,
ECP operates using a parallel SEM beam, in channeling mode, and an image is formed by scanning a sample crystal during the image exposure time;
EBSD operates using a focused SEM beam, a large specimen tilt relative to both the illuminating rays and to an EBSD detector, and an image is formed while the sample crystal location is static, not moving, during the image exposure time.

Table 1 below summarizes characteristics of the above-mentioned methods and in the last line presents characteristics of example methods described herein.

TABLE 1

| | | | | Angle of | |
|---|---|---|---|---|---|
| | | | | imager | |
| | | | | optical axis | |
| | Focused/ | Image(s) | Angle of beam to | to normal | |
| Method | parallel | formed by | normal to surface | to surface | Analysis of |
| ECP | parallel | Scanning | varies several | Any | Image of |
| | | sample at small | degrees around a | | Kikuchi pattern |
| | | magnification | chosen direction | | |
| EBSD | focused | Fixed location | Fixed at large | Large (>45 | Image of |
| | | | (>45 degrees) | degrees) | Kikuchi pattern |
| | | | angle | | |
| New | focused | Scanning | Imaged at | Any | differences |
| method(s) | | sample at large | different angles | | between images |
| described | | magnification | | | captured at |
| herein | | | | | different angles |

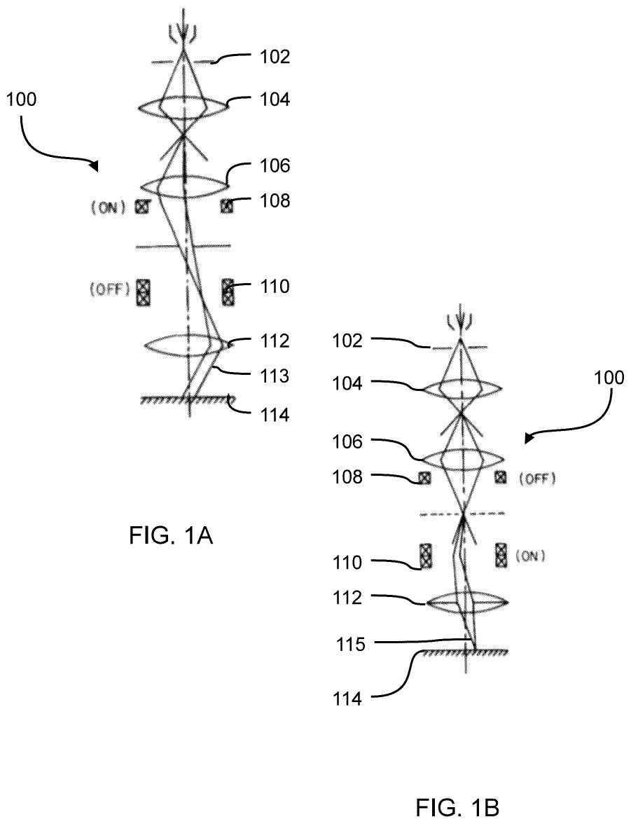

Reference is now made to FIGS. 1A and 1B, which are simplified illustrations of an example three-lens scanning electron microscope (SEM) according to prior art.

FIGS. 1A and 1B show a SEM 100 having an electron beam source 102, an electron beam condenser lens 104, an electron beam intermediate lens 106, a first scan coil 108, a second scan coil 110, and an electron beam objective lens 112. FIGS. 1A and 1B also show sample crystal 114.

FIG. 1A shows an example where the first scan coil 108 is in an “ON” state, and the second scan coil 110 is in an “OFF” state, arranged so that the electron beam 113 incident upon the sample crystal 114 is a parallel electron beam. Providing a parallel electron beam is also termed “channeling mode”.

FIG. 1B shows an example where the first scan coil 108 is in an “OFF” state, and the second scan coil 110 is in an “ON” state, arranged so that the electron beam 115 incident upon the sample crystal 114 is focused on the surface of the sample crystal 114. Providing a focused electron beam is also termed “image mode” or “imaging mode”.

A method is described herein which teaches how to use a focused beam SEM to determine physical features of crystals, such as crystal lattice spacing and crystal lattice orientation.

As described above, a cross section of a focused beam SEM has a diameter approximately 100 times smaller than the diameter of a parallel beam (channeling mode) SEM, thus enabling to determine physical features of crystals in an area approximately 10,000 smaller.

When using a SEM, the wavelength of the radiation λ is determined by the beam energy of the electrons.

In some examples, the angle of incidence θ of the electron beam on a crystal sample is determined by tilting a SEM specimen stage relative to an optic axis of the electron beam.

In some examples, the angle of incidence θ of the electron beam on the crystal sample is determined by tilting an angle of the SEM electron beam optic axis relative to the SEM specimen stage. Such examples are often used in cases of large semiconductor wafers which typically do not have enough room in a SEM specimen chamber to be tilted at a large angle.

In some examples, the angle of incidence θ) of the electron beam on the crystal sample is determined by combining a tilting of the SEM specimen stage relative to the optic axis of the electron beam and tilting an angle of the SEM electron beam optic axis relative to the SEM specimen stage.

The terms “tilt” and “tilting” in all their grammatical forms are used interchangeably with the terms “rock” and “rocking” in all their grammatical forms in the present application and claims.

### Example Physical Features Determined by the Focused Beam Method

An example physical feature which can be determined using a SEM is crystal orientation. A sample specimen is tilted and reflected radiation is measured, and then one determines by what angle the tilt of the sample specimen at maximum reflection, or at one of the Bragg angles, differs from an angle expected to be for the sample specimen. The difference determines the difference in orientation of at least one of the crystal axes from an orientation expected to be for the sample specimen.

An example physical feature which can be determined using a SEM in focused beam mode is crystal lattice spacing. A sample specimen is tilted at different tilt angles, and reflected radiation is measured at each angle. A Bragg angle is determined, and then one uses Bragg's formula to determine the lattice spacing.

An example physical feature which can be determined using a SEM is crystal lattice strain. A sample specimen is tilted at different tilt angles, and reflected radiation is measured at each angle. A Bragg angle is determined, and then one uses Bragg's formula to determine the lattice spacing. When the lattice spacing is not the lattice spacing expected by the chemical composition of the sample specimen, the sample specimen is apparently strained to a degree which changes its lattice spacing. Such can occur, by way of some non-limiting examples: in an epitaxial layer where its composition has a first lattice spacing which is deposited upon a crystal layer which has a different lattice spacing; and in a crystal which has a local defect.

Example Showing that a Focused Beam can Provide Crystal Features

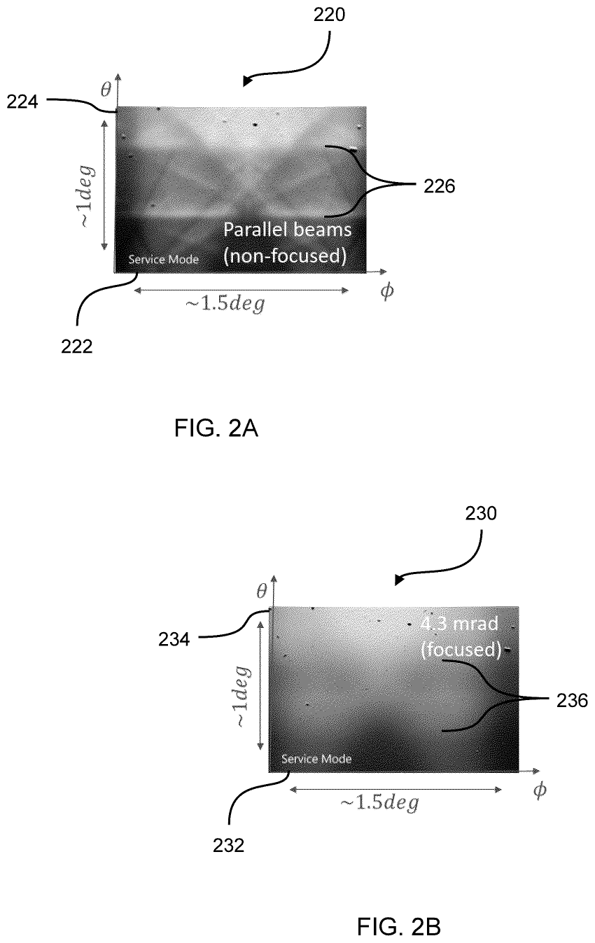

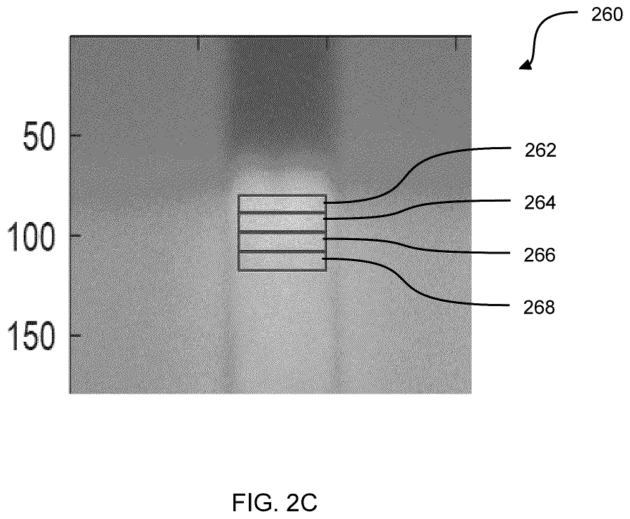

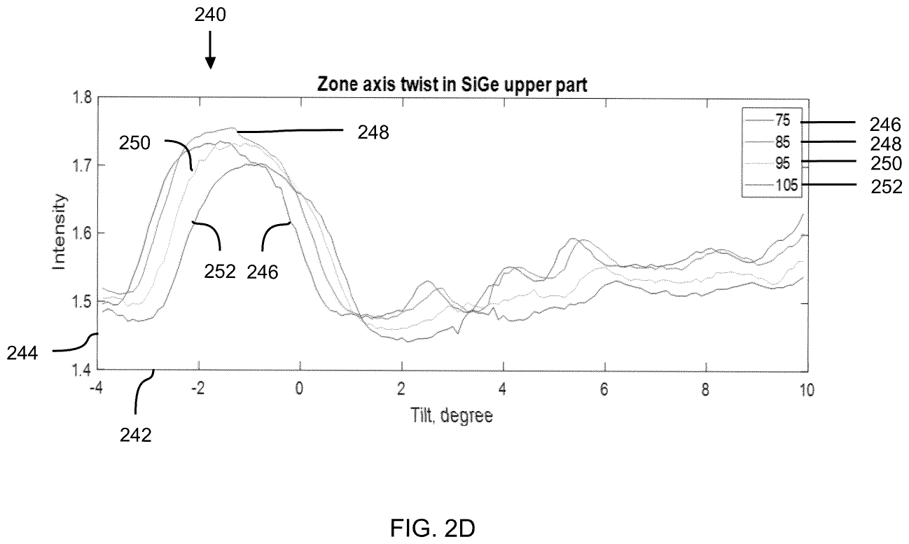

Reference is now made to FIG. 2A, which is a SEM image produced using a parallel, unfocused electron beam at a tilt angle of 34 degrees to a lattice plane of a silicon wafer according to an example.

FIG. 2A is a SEM image produced by the ECP method.

FIG. 2A shows an image 220 with a field of view (FOV) of approximately 1 mm. The image 220 shows an X-axis 222 showing a range of 1.5 degrees around a direction of the unfocused electron beam and a Y-axis 224 showing a range of 1 degree around the direction of the unfocused electron beam.

The illuminating electron beam of FIG. 2A is a parallel, unfocused beam, which produces an image 220 which includes diffraction patterns called Kikuchi lines 226.

Analyzing the locations, angles and distance between the Kikuchi lines enables calculation of crystal properties such as, by way of a non-limiting example, the crystal lattice spacing and lattice planes orientations.

Reference is now made to FIG. 2B, which is a SEM image produced using a focused electron beam with a central optical axis at a tilt angle of 34 degrees to a lattice plane of a of a silicon wafer according to an example.

FIG. 2B is a SEM image produced by a focused electron beam, and so different from the ECP method.

FIG. 2B shows an image 230 with a field of view (FOV) of approximately 1 mm. The image 220 shows an X-axis 232 showing a range of 1.5 degrees around a direction of the central optical axis of the focused electron beam and a Y-axis 234 showing a range of 1 degree around a direction of the central optical axis of the focused electron beam.

The illuminating electron beam of FIG. 2B is a focused beam, having a convergent angle of 4.3 milliradians.

Despite the illuminating electron beam not being a parallel beam, FIG. 2B still shows a diffraction pattern of Kikuchi lines 236, but less sharp than in FIG. 2A.

However, when one scans the image 230, one can find locations of peaks and valleys of the less-sharp Kikuchi lines, corresponding to the Kikuchi lines of the sharper FIG. 2A.

Analyzing the locations angles and distances between the Kikuchi lines of FIG. 2B also enables calculation of crystal properties such as, by way of a non-limiting example, the crystal lattice spacing and lattice planes orientations.

Reference is now made to FIGS. 2C and 2D, which are simplified illustrations of measuring crystal orientation according to an example.

FIG. 2C is a color image, displayed as grey scale in the present application, which by different colors or grey scale intensities illustrates different intensities reflected from different locations on a Germanium on Silicon crystal sample.

The crystal sample was epitaxial Germanium on Silicon, and different colors or intensities reflected from f-different locations indicate different crystal lattice orientations.

Four 10-nm×30-nm adjacent rectangular areas on the crystal sample are referenced by reference numbers 262, 264, 266, 268 corresponding to areas centered at coordinates of 75 microns, 85 microns, 95 microns and 105 microns respectively.

When one compares the areas referenced by reference numbers 262, 264, 266, 268, one sees that the area referenced by reference number 268 has a different intensity than the area referenced by reference number 262, for example, thereby indicating different crystal lattice orientations at these locations.

The Germanium on Silicon crystal sample was rocked over a range of small angles from −4 degrees to +10 degrees, and the electron radiation intensity reflected was measured.

FIG. 2D is a graph illustrating reflected electron radiation intensity at the different angles.

FIG. 2D is a graph 240 with an X-axis 242 showing tilt angles in degrees, and a Y-axis 244 showing qualitative intensity of reflected electron radiation.

The graph 240 shows 4 lines referenced 246 248 250 252 corresponding to reflected radiation at the four areas referenced by reference numbers 262, 264, 266, 268 in FIG. 2C.

A first line 246 shows a peak reflection at an angle of −1.5 degrees.

A second line 248 shows a peak reflection at an angle of −1.3 degrees.

A third line 250 shows a peak reflection at an angle of −1.2 degrees.

A fourth line 252 shows a peak reflection at an angle of −1 degrees.

Peak reflection corresponds to a direction of crystal orientation.

The graph 240 demonstrates (a) that crystal orientation can be measured by a focused SEM electron beam in a small area, of 30×10 nm, and (b) that different crystal orientations can be measured to be different at different locations located not more than 10 nm apart.

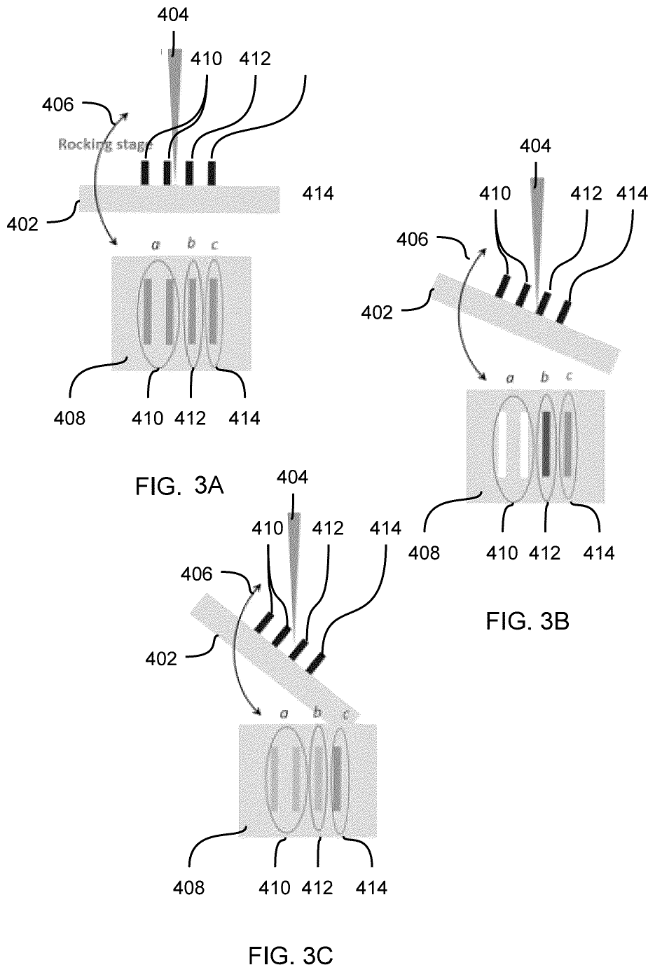

Reference is now made to FIGS. 3A, 3B and 3C, which are simplified illustrations of various crystalline and amorphous samples imaged by a focused SEM beam at various tilt angles, according to some examples.

FIGS. 3A, 3B and 3C show, in a top portion, a cross-sectional side view of a tiltable or rocking stage 402, upon which are deployed four samples 410 412 414, scanned by a focused SEM beam 404, and in a bottom portion, a top view of the tiltable or rocking stage 408, upon which are deployed the four samples 410 412 414, scanned by the focused SEM beam 404.

The various crystalline and amorphous samples include different crystalline samples 410, and 412, and an amorphous sample 414. The difference between samples 410 and 412 may be lattice orientation, crystalline phase, or chemical composition.

FIG. 3A shows the samples 410 412 414 with the tilting stage 402 408 at a first angle to an optic axis of the focused SEM beam 404. FIG. 3A shows an example case where the reflectance at the first angle of the three samples 410 412 414 is similar, as can be seen by the areas of the three samples 410 412 414 having a similar grey fill in the top view.

FIG. 3B shows the samples 410 412 414 with the tilting stage 402 408 at a second angle to the optic axis of the focused SEM beam 404. FIG. 3B shows that at the second angle, which is different from the first angle, the reflectance of the three samples 410 412 414 is different from each other. For example, the samples 410 reflect more than at the first angle, the sample 412 reflects less than at the first angle, while the sample 414, being amorphous, only somewhat changes its reflectance.

FIG. 3C shows the samples 410 412 414 with the tilting stage 402 408 at a third angle to the optic axis of the focused SEM beam 404. FIG. 3C shows that at the third angle, which is even more tilted than the second angle, the reflectance of the three samples 410 412 414 is again different from each other. For example, the samples 410 reflect somewhat less than at the first angle, and much less than at the second angle, the sample 412 reflects somewhat less than at the first angle and yet more than at the second angle, while the sample 414, being amorphous, changes its reflectance to somewhat less than at the second angle.

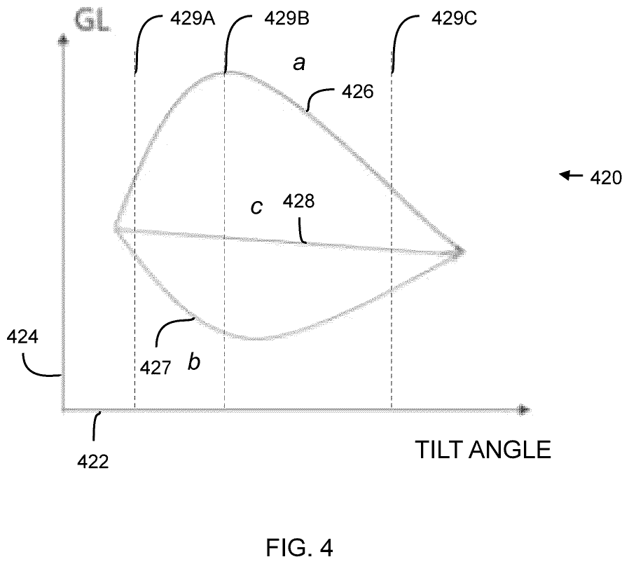

Reference is now made to FIG. 4, which is a graph of qualitative values of reflected radiation amplitude of the various crystalline and amorphous or non-crystalline samples of FIGS. 3A, 3B and 3C, according to some examples.

FIG. 4 shows a graph 420 having an X-axis 422 of tilt angle of the tilting stage of FIGS. 3A, 3B and 3C, a Y-axis 424 showing reflectance intensity, and three lines 426 427 428 corresponding to the reflectance intensity of the three samples of FIGS. 3A, 3B and 3C.

A first line 426 corresponds qualitatively to changes in reflectance intensity of the first sample 410 as the tilt angle of the stage 402 408 changes.

A second line 427 corresponds qualitatively to changes in reflectance intensity of the second sample 412 as the tilt angle of the stage 402 408 changes.

A third line 427 corresponds qualitatively to changes in reflectance intensity of the third sample 414 as the tilt angle of the stage 402 408 changes.

It is noted that for the crystalline samples 410 412 the reflectance is relatively strongly, and possibly also non-monotonically, tilt dependent.

It is noted that for the amorphous or amorphous or non-crystalline sample 414 the reflectance is relatively weakly, and possibly monotonically or quasi monotonically, tilt dependent.

It is noted that angular sensitivity of measurement is associated with beam apex angle of the focused SEM beam.

It is noted that tilt minimum step in a current production SEM is about 0.1 degrees.

Three vertical lines 429A 429B 429C have been added to the graph of FIG. 4.

A first vertical line 429A shows that, at a first tilt angle, the three samples of FIGS. 3A, 3B and 3C can be differentiated by virtue of different reflectance values.

A second vertical line 429B and a third vertical line 429C show that, at a second tilt angle, and at a third tilt angle, the three samples of FIGS. 3A, 3B and 3C can be differentiated by virtue of different reflectance values.

It is noted that at most tilt angles crystals having different crystal features can be identified based on their reflectance values.

### Analysis

FIG. 4 shows that, for a location on an area which is as small as the resolution of a focused-beam SEM, different crystalline materials can be differentiated by measuring reflection intensity, whether using reflection intensity data at one specific tilt angle, or by tracking.

Various methods of analysis can be applied, based, by way of a non-limiting examples, on data such as produced the graph of FIG. 4.

One non-limiting example of a method can be producing focused SEM images at various tilt angles and comparing the images. Locations which are supposed to have the same crystalline features are supposed to have similar reflectance at similar tilt angles. If they do not, a crystalline defect can be detected at a location exhibiting different reflection than similar locations.

One non-limiting example of a method can be producing focused SEM images at various tilt angles, correcting geometry of the images to compensate for the tilt and comparing the images. Locations which are supposed to have the same crystalline features are supposed to have similar reflectance at similar tilt angles. If they do not, a crystalline defect can be detected at a location exhibiting different reflection than similar locations.

One non-limiting example of a method can be producing focused SEM images of a sample material, for example silicon wafer, or silicon-germanium wafer, at various tilt angles and measuring reflectance at a specific location. The measured reflectance can be compared to a lookup table which contains tilt angles and reflectance values associated with the sample material. If the measured reflectance at the location and the expected reflectance according to the lookup table are different, a defect may be determined at the location.

One non-limiting example of a method can be producing focused SEM images of a sample material, for example silicon wafer, or silicon-germanium wafer, at various tilt angles and measuring reflectance at a specific location. The measured reflectance at the specific location can be tracked at different tilt angles, producing data like the graphs shown in in FIG. 4, and using the data to detect Bragg angles and calculate crystal features such as crystal spacing or crystal stress.

One non-limiting example of a method can be producing focused SEM images of a sample material, for example silicon wafer, or silicon-germanium wafer, at various tilt angles and measuring reflectance at a specific location. The measured reflectance at the specific location can be compared to reflectance of a reference material with known crystal properties, by way of a non-limiting example Si at the same tilt angles. A shift of a pattern of Kikuchi lines is associated with a change of angle between lattice planes in an investigated sample and may be used to determine local crystal features. The reflectance of reference material may be provided by measuring reflectance of the reference material at a location known to be amorphous, or by looking up in a lookup table, or by computer simulation.

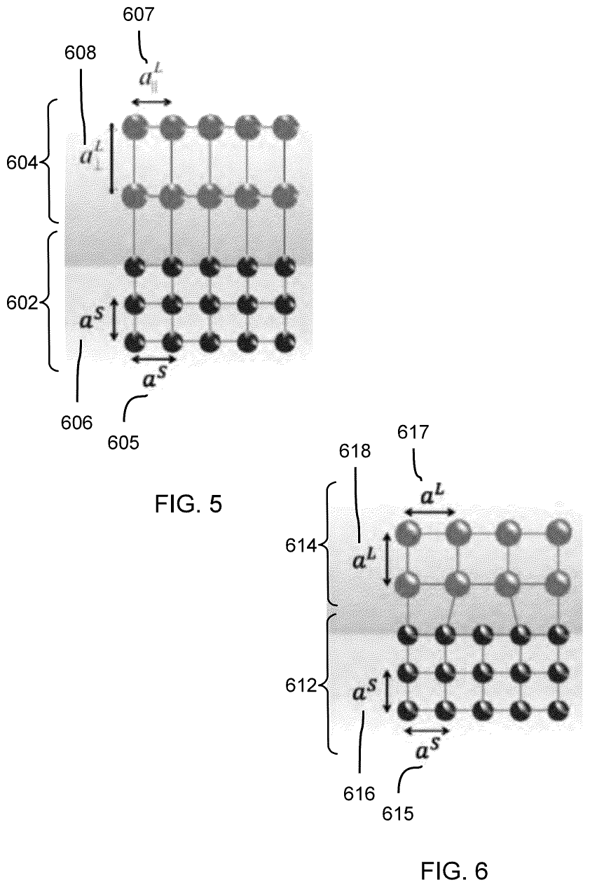

Reference is now made to FIG. 5, which shows a simplified cross-sectional drawing of a strained epitaxial layer on a substrate layer according to an example.

FIG. 5 shows a substrate crystalline layer 602 having a lateral lattice spacing

$${a}_{‖}^{S}$$

605 and a vertical lattice spacing

$${a}_{⊥}^{S}$$

606, and an epitaxial crystalline layer 604 having a lateral lattice spacing

$${a}_{‖}^{L}$$

607 and a vertical lattice spacing

$${a}_{⊥}^{L}$$

608.

The substrate crystalline layer 602 has a smaller lattice spacing than the epitaxial crystalline layer 604.

In the case shown in FIG. 5, the epitaxial layer's lateral lattice spacing

$${a}_{‖}^{L}$$

607 is forced to be the same as the substrate layer's lateral lattice spacing

$${a}_{∥}^{S}$$

605, and such a condition is termed a strained, even a fully strained, epitaxial layer.

Reference is now made to FIG. 6, which shows a simplified cross-sectional drawing of a relaxed epitaxial layer on a substrate layer according to an example.

FIG. 6 shows a substrate crystalline layer 612 having a lateral lattice spacing

$${a}_{∥}^{S}$$

615 and a vertical lattice spacing

$${a}_{⊥}^{S}$$

616, and an epitaxial crystalline layer 614 having a lateral lattice spacing

$${a}_{∥}^{L}$$

617 and a vertical lattice spacing

$${a}_{⊥}^{L}$$

618.

The substrate crystalline layer 612 has a smaller lattice spacing than the epitaxial crystalline layer 614.

In the case shown in FIG. 6, not all the epitaxial layer's atoms or molecules are bonded to all the substrate layer's atoms or molecules, providing some relaxation of the strain between the epitaxial layer and the substrate layer.

In the case shown in FIG. 6, the epitaxial layer's lateral lattice spacings

$${a}_{∥}^{L}$$

617 are not all forced to be the same as the substrate layer's lateral lattice spacing

$${a}_{∥}^{S}$$

615, and such a condition is termed a relaxed, or even a fully relaxed, epitaxial layer.

It is noted that the lattice spacings, both lateral and vertical, can be measured by tilting an epitaxial crystalline sample and discovering the lattice spacing using the methods described above.

It is noted again that a typical non-focused beam in channeling mode has a radius of approximately 100 nanometers, or 1/10 of a micron. Using a focused beam SEM enables detecting crystal strain or relaxation at a geometric scale far smaller than 1/10 of a micron.

It has been demonstrated that lattice spacing on a sample surface, for example on an epitaxial layer, can be measured, that is, the values of lateral

$${a}_{∥}^{L}$$

and vertical

$${a}_{⊥}^{L} .$$

The values of lateral

$${a}_{∥}^{S}$$

and vertical

$${a}_{⊥}^{S} ,$$

of the substrate crystal, can be obtained, either by imaging an area where the substrate is open to the SEM imaging, or by imaging a reverse of an epitaxial specimen, or by obtaining known values for the substrate layer.

Once

$${a}_{∥}^{L} , {a}_{⊥}^{L} , {a}_{∥}^{S} and {a}_{⊥}^{S}$$

are known, the following values of physical features can be computed:

$$Lattice misfit : δ = \frac{{a}^{L} - {a}^{S}}{{a}^{S}} ;$$

$$Lattice strain : {ε}_{∥} = \frac{{a}_{∥}^{L} - {a}^{L}}{{a}^{L}} , {ε}_{⊥} = \frac{{a}_{⊥}^{L} - {a}^{L}}{{a}^{L}} ;$$

$$Relaxation parameter : R = \frac{{a}_{∥}^{L} - {a}^{S}}{{a}^{L} - {a}^{S}} ;$$

For an example SiGe epitaxial sample, the following is true,

$${a}^{L} = {a}_{S i G e} = {a}_{S i} ( 1 - x ) + {a}_{G e} x - 0.026 x ( 1 - x )$$

And the lattice constants for pure silicon and pure germanium are:

$${a}_{S i} = 5.43102 Å ; and$$

$${a}_{G e} = 5.6549 Å .$$

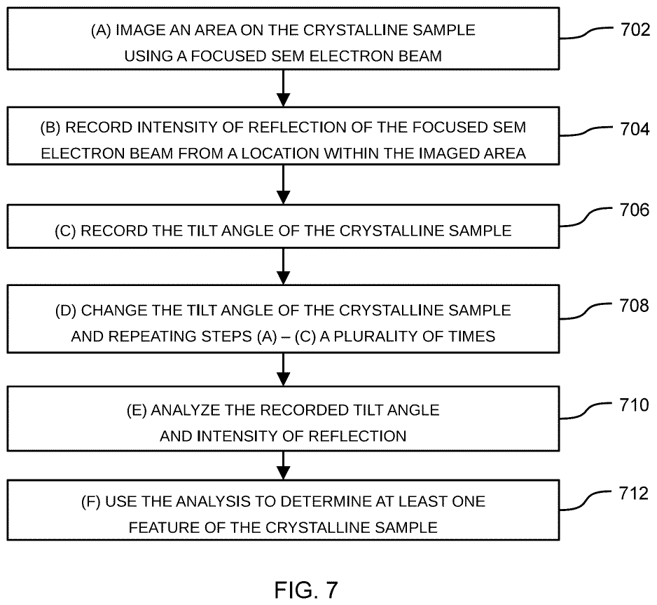

Reference is now made to FIG. 7, which is a simplified flow chart illustration of a method of using a scanning electron microscope (SEM) to determine crystalline features of a crystalline sample, according to an example.

The method of FIG. 7 includes:
(a) imaging an area on the crystalline sample using a focused SEM electron beam (702);
(b) recording intensity of reflection of the focused SEM electron beam from a location within the imaged area (704);
(c) recording the tilt angle of the crystalline sample (706);
(d) changing the tilt angle of the crystalline sample and repeating steps (a)-(c) a plurality of times (708);
(e) analyzing the recorded tilt angle and intensity of reflection (710);
(f) using the analysis to determine at least one feature of the crystalline sample (712).

### Calibration

In some examples, a discovered tilt angle at an extremum of reflected intensity may optionally be used in a calculation involving Bragg's formula to discover lattice spacing of a sample crystal.

In some examples, a calibration procedure may be used, wherein a known crystal sample, at a known crystal orientation, is placed in a SEM, the stage rocked, and reflectance measured. Tilt angles of local extrema of are optionally recorded.

In some examples, the tilt angles of local extrema are recorded together with additional settings under which the known crystal sample was measured, such as electron beam energy, SEM model, and SEM focus settings.

Such a set of recorded data is optionally compared to measurement of a sample crystal being measured at a specific location, and the comparison is optionally used to determine crystal properties of the sample crystal at the specific location.

By way of a non-limiting example, a consistent deviation of several reflectance extrema by a first angle may be taken to mean that the sample crystal orientation is different from the calibration crystal orientation by an amount equal to the first angle.

By way of another non-limiting example, a deviation of several reflectance extrema by different angles may be taken to mean that the sample crystal lattice spacing is different from the calibration crystal lattice spacing.

In some examples several known crystal samples may be used to set up calibration data, and a sample crystal under test may be found to possess the same measurements as one of the known crystals.

### SUMMARY OF THE PRESENT DISCLOSURE

### Example 1

A method of using a scanning electron microscope (SEM) to determine crystalline features of a crystalline sample, the method including:
(a) imaging an area on the crystalline sample using a focused SEM electron beam,
(b) recording intensity of reflection of the focused SEM electron beam from a location within the imaged area,
(c) recording a tilt angle of the crystalline sample,
(d) changing the tilt angle of the crystalline sample and repeating steps (a)-(c) a plurality of times for the imaged area,
(e) analyzing the recorded tilt angles and intensities of reflection,
(f) using the analysis to determine at least one crystalline feature of the crystalline sample.

### Example 2

The method of example 1 wherein a spatial resolution of the imaged area is on an order of a radius of the focused SEM electron beam at the location.

### Example 3

The method of any one of examples 1-2 wherein the crystalline sample includes a semiconductor wafer.

### Example 4

The method of any one of examples 1-3 wherein the analyzing includes finding a local extremum of the recorded intensity of reflection values in a line defined by the recorded tilt angle values and the recorded intensities of reflection values, and using a tilt angle associated with the local extremum in Bragg's formula to determine the at least one feature of the crystalline sample.

### Example 5

The method of any one of examples 1-4 wherein the analyzing includes finding a local extremum of the recorded intensity of reflection values in a line defined by the recorded tilt angle values and the recorded intensity of reflection values, and using a tilt angle associated with the local extremum and an associated Kikuchi line to determine the at least one feature of the crystalline sample.

### Example 6

The method of any one of examples 1-5 wherein a radius of the location is less than 20 nanometers.

### Example 7

The method of any one of examples 1-6 wherein a radius of the location is less than 2 nanometers.

### Example 8

The method of any one of examples 1-7 wherein the analyzing includes determining crystal lattice spacing at the location.

### Example 9

The method of any one of examples 1-8 wherein the analyzing includes determining crystal lattice orientation at the location.

### Example 10

The method of any one of examples 1-9 wherein the analyzing includes determining whether the crystalline specimen is stressed at the location based on the lattice spacing and the lattice orientation.

### Example 11

The method of any one of examples 1-10 wherein the analyzing includes determining directional dielectric constant at the location.

### Example 12

The method of any one of examples 1-11 wherein the analyzing includes determining directional conductivity at the location.

### Example 13

The method of any one of examples 1-12 wherein the analyzing includes determining directional reflectivity at each tilt angle of the crystalline sample.

### Example 14

A method of using a scanning electron microscope (SEM) to determine crystalline features of a crystalline sample, the method including:
(a) imaging an imaged area on a semiconductor wafer using a focused SEM electron beam,
(b) recording intensity of reflection of the focused SEM electron beam at a plurality of locations within the imaged area,
(c) recording a tilt angle of the semiconductor wafer,
(d) changing the tilt angle of the semiconductor wafer and repeating steps (a)-(c) a plurality of times for the imaged area,
(e) analyzing the recorded tilt angles and intensities of reflection,
(f) using the analysis to determine at least one crystalline feature of the semiconductor wafer for at least one of the plurality of locations.

As such, those skilled in the art to which the present invention pertains, can appreciate that while the present invention has been described in terms of preferred examples, the concept upon which this disclosure is based may readily be utilized as a basis for the designing of other structures, systems and processes for carrying out the several purposes of the present invention.

Also, it is to be understood that the phraseology and terminology employed herein are for the purpose of description and should not be regarded as limiting.

It should be noted that the words “comprising”, “including” and “having” as used throughout the appended claims are to be interpreted to mean “including but not limited to”. The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases, and disjunctively present in other cases.

It is important, therefore, that the scope of the invention is not construed as being limited by the illustrative examples set forth herein. Other variations are possible within the scope of the present invention as defined in the appended claims. Other combinations and sub-combinations of features, functions, elements and/or properties may be claimed through amendment of the present claims or presentation of new claims in this or a related application. Such amended or new claims, whether they are directed to different combinations or directed to the same combinations, whether different, broader, narrower or equal in scope to the original claims, are also regarded as included within the subject matter of the present description.

It is expected that during the life of a patent maturing from this application various relevant crystals will be adopted for use and the scope of the term crystal is intended to include all such crystals a priori.

It is expected that during the life of a patent maturing from this application various relevant SEMs may be developed and the scope of the term SEM is intended to include all such SEMs a priori.

As used herein with reference to quantity or value, the term “approximately” means “within ±50% of”.

The terms “comprising”, “including”, “having” and their conjugates mean “including but not limited to”.

The term “consisting of” is intended to mean “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a unit” or “at least one unit” may include a plurality of units, including combinations thereof.

The words “example” and “exemplary” are used herein to mean “serving as an example, instance or illustration”. Any embodiment described as an “example or “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the disclosure may include a plurality of “optional” features unless such features conflict.

Unless otherwise indicated, numbers used herein, and any number ranges based thereon are approximations within the accuracy of reasonable measurement and rounding errors as understood by persons skilled in the art.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. Certain features described in the context of various embodiments are not to be considered essential features of those embodiments, unless the embodiment is inoperative without those elements.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. A method of using a scanning electron microscope (SEM) to determine crystalline features of a crystalline sample, the method comprising:
(a) imaging an area on the crystalline sample using a focused SEM electron beam;
(b) recording intensity of reflection of the focused SEM electron beam from a location within the imaged area;
(c) recording a tilt angle of the crystalline sample;
(d) changing the tilt angle of the crystalline sample and repeating steps (a)-(c) a plurality of times for the imaged area;
(e) analyzing the recorded tilt angles and intensities of reflection;
(f) using the analysis to determine at least one crystalline feature of the crystalline sample.

2. The method of claim 1 wherein a spatial resolution of the imaged area is on an order of a radius of the focused SEM electron beam at the location.

3. The method of claim 1 wherein the crystalline sample comprises a semiconductor wafer.

4. The method of claim 1 wherein the analyzing comprises:
finding a local extremum of the recorded intensity of reflection values in a line defined by the recorded tilt angle values and the recorded intensities of reflection values; and
using a tilt angle associated with the local extremum in Bragg's formula to determine the at least one feature of the crystalline sample.

5. The method of claim 1 wherein the analyzing comprises:
finding a local extremum of the recorded intensity of reflection values in a line defined by the recorded tilt angle values and the recorded intensity of reflection values; and
using a tilt angle associated with the local extremum and an associated Kikuchi line to determine the at least one feature of the crystalline sample.

6. The method of claim 1 wherein a radius of the location is less than 2 nanometers.

7. The method of claim 1 wherein the analyzing comprises determining crystal lattice spacing at the location.

8. The method of claim 1 wherein the analyzing comprises determining crystal lattice orientation at the location.

9. The method of claim 1 wherein the analyzing comprises determining whether the crystalline specimen is stressed at the location based on the lattice spacing and the lattice orientation.

10. The method of claim 1 wherein the analyzing comprises determining directional dielectric constant at the location.

11. The method of claim 1 wherein the analyzing comprises determining directional conductivity at the location.

12. The method of claim 1 wherein the analyzing comprises determining directional reflectivity at each tilt angle of the crystalline sample.

13. A method of using a scanning electron microscope (SEM) to determine crystalline features of a crystalline sample, the method comprising:
(a) imaging an imaged area on a semiconductor wafer using a focused SEM electron beam;
(b) recording intensity of reflection of the focused SEM electron beam at a plurality of locations within the imaged area;
(c) recording a tilt angle of the semiconductor wafer;
(d) changing the tilt angle of the semiconductor wafer and repeating steps (a)-(c) a plurality of times for the imaged area;
(e) analyzing the recorded tilt angles and intensities of reflection;
(f) using the analysis to determine at least one crystalline feature of the semiconductor wafer for at least one of the plurality of locations.
